(19) United States
(12) Patent Application Publication
(10) Pub. No.: US 2026/0026049 A1
(43) Pub. Date: Jan. 22, 2026

(54) QUANTUM DEVICE WITH SEMICONDUCTOR QUBITS COMPRISING GATES ARRANGED IN A SEMICONDUCTOR

(71) Applicant: COMMISSARIAT A L'ENERGIE ATOMIQUE ET AUX ENERGIES ALTERNATIVES, Paris (FR)

(72) Inventors: Silvano DE FRANCESCHI, Grenoble (FR); Biel MARTINEZ I DIAZ, Grenoble (FR); Yann-Michel NIQUET, Grenoble (FR)

(73) Assignee: COMMISSARIAT A L'ENERGIE ATOMIQUE ET AUX ENERGIES ALTERNATIVES, Paris (FR)

(21) Appl. No.: 18/881,396

(22) PCT Filed: Jul. 7, 2023
(86) PCT No.: PCT/FR2023/051049

§ 371 Date: Jan. 6, 2025

(30) Foreign Application Priority Data
Jul. 8, 2022 (FR) FR2207043

(51) Int. Cl. H10D 48/00; B82Y 10/00; H10D 48/01; H10D 62/822; H10D 62/824; H10D 64/27

(52) U.S. Cl. CPC H10D 48/383; B82Y 10/00; H10D 48/031; H10D 62/822; H10D 62/824; H10D 64/27

(57) ABSTRACT

A quantum device with semiconductor qubits, comprising at least: a layer of a first semiconductor arranged on a layer of a second semiconductor, the forbidden energy band of which is different from that of the first semiconductor, such that one of the layers forms a confinement potential barrier with respect to the electrons or the holes intended to be located in confinement regions formed in the other layer; cavities formed through only one portion of the thickness of the layer of the first semiconductor; and electrically conductive control gates at least partially arranged individually in one of the cavities.

### TECHNICAL FIELD

The invention relates to the field of quantum devices, the processing of quantum information and quantum computing. Advantageously, the invention applies to the development of quantum processors wherein qubits, i.e. the elementary quantum information units, are encoded in semiconductor quantum dots, in particular for spin qubits where the quantum information is encoded in the spin states (i.e. the magnetic moments) of electrons or holes confined by electrostatic potentials and/or possibly of the micro-structuring, or for charge qubits where the quantum information is encoded in the confined electrical charge.

### PRIOR ART

Quantum computing is based on the use of a quantum state with two measurable levels as an information vector, so-called a quantum bit, or, in one single word, “qubit”. Laws and properties of quantum mechanics, such as superposition, entanglement, and measurement are exploited in order to execute algorithms. A quantum device comprising qubits allows manipulating the quantum state of these qubits.

The spin or charge qubits may be formed in semiconductor. Semiconductor technologies are studied for making qubits because of their high integration potential, like conventional electronics. In such qubits, electrons or holes are confined at cryogenic temperatures in confinement structures with nanometric sizes defined electrostatically and, in the case of silicon, with an architecture close to that of MOSFETs. These confinement structures correspond to quantum dots. A quantum dot behaves like a potential well confining one or more elementary charge(s) (electrons or holes) in a semiconductor region.

For a quantum processor to be able to solve problems of practical importance, it should include a sufficiently large number of qubits, beyond the maximum number of qubits that could be simulated on a conventional computing machine (i.e. more than about 50 qubits). Nonetheless, making of such a number of qubits within the same device poses technological problems, in particular the management of the variability between the qubits.

In a quantum device with semiconductor qubits (spin or charge qubits), the electrons or the holes used for encoding the quantum information are confined using metallic gates deposited above a structure or heterostructure of semiconductor(s) covered with a layer of an insulating material (SiO₂, Al₂O₃, etc.) serving as a gate oxide. There could be one or more metallic gate level(s) superposed and separated by layers of an insulating material. The electrons or the holes are confined in the semiconductor portion located under the gates (vertically in line with or in the vicinity of these), or at the interface between the semiconductor and the gate oxide, or in buried quantum wells created by the stack of semiconductor layers of different compositions. For example, such a quantum well includes a silicon or germanium portion in which charge carriers (electrons in the case of silicon, holes in the case of germanium) are confined by SiGe barriers between which the silicon or germanium portion is located. In all cases, the confinement of the electrons or of the holes is sensitive to the presence of electrical charges trapped mainly at the interfaces between the semiconductor structure and the dielectric material(s) deposited over its surface. This charge disorder is one of the main causes of variability between qubits.

If the electric field generated by the charges trapped directly under the metallic gates is partially screened by the gates, that one generated by the charges between the gates is much less. Consequently, the charges disorder associated with the semiconductor/dielectric interfaces that are relatively remote from the metallic gates has a dominant effect on the variability between qubits.

### DISCLOSURE OF THE INVENTION

The present invention aims to provide a quantum device with semiconductor qubits which structure allows substantially reducing the variability between the qubits.

For this purpose, the present invention provides a quantum device with semiconductor qubits, including at least:
a layer of a first semiconductor arranged over a layer of a second semiconductor which bandgap energy is different from that of the first semiconductor, such that one of the layers forms a confinement potential barrier to electrons or holes intended to be located in confinement regions formed in the other layer;
cavities formed through only a portion of the thickness of the layer of the first semiconductor,
electrically-conductive control gates, each arranged at least partially in one of the cavities.

This device could be applied to all qubits made from a semiconductor heterostructure wherein the vertical confinement (or direction parallel to the stacking direction, or growth direction, of the semiconductor layers) of the charge carriers (electrons or holes) takes place in one of the semiconductor layers forming potential wells.

In order to reduce the effect of the charge disorder associated with the semi-conductor/oxide surface interfaces not covered by metallic gates, this quantum device provides for the use of a structure of so-called “penetrating” gates, i.e. made within one of the semiconductor layers. Compared to conventional gates with a gate dielectric formed above the semiconductor stack forming the quantum wells, this geometry of the gates allows bringing the semiconductor/dielectric interfaces between adjacent gates away, and, consequently, reducing the impact of the associated charges disorder and of the charges noise, and therefore reducing the variability between the qubits of the device. This reduction in the variability of the qubits allows simplifying the control architecture associated with this quantum device and facilitating the adjustment of the qubits.

In this device, encoding the quantum information could take place on a degree of freedom of a spin (i.e. the spin states of a particle in the presence of a static magnetic field) or of a charge of electrons or holes trapped in the confinement regions, or on charges present in the confinement regions.

The invention advantageously applies to a quantum device including at least 50 qubits.

Such a quantum device differs from a MOSFET device by the fact that the semiconductor regions located next to the quantum dots surmounted by the control gates form “tunnel barriers” which isolate the quantum dots from one another.

Each of the control gates could be used to form a quantum dot or to control the height of one of the tunnel barriers located between two quantum dots, i.e. to control the coupling between these dots. In the case of a control gate used to form a quantum dot, the confinement region of this quantum dot is generally located in the vicinity of the interface between the layers of the first and second semiconductors, vertically in line with the cavities or in the vicinity of these.

The confinement regions are created by all or part of the control gates according to the potential applied respectively thereto. In other words, a qubit is not necessarily associated with each control gate.

According to the embodiment of the method implemented to form the control gates in the cavities, these may partially or totally fill the cavities. The material of the control gates could also overflow from the cavities.

Each of the control gates may include at least one metallic material.

Advantageously, in a first embodiment:
the semiconductor of said one of the layers forming the confinement potential barrier may be AlGaAs and the semiconductor of said other layer may be GaAs, or
the semiconductor of said one of the layers forming the confinement potential barrier may be SiGe and the semiconductor of said other layer may be Si or Ge.

Beyond these combinations of semiconductor materials, the invention could be applied in general to any type of heterostructure obtained by stacking two different semiconductor materials, like, for example, the following pairs of materials: InAs/InGaAs, InGaAs/InP, CdTe/HgTe, etc.

In a second embodiment, the device may further include a layer of a third semiconductor such that the layer of the second semiconductor is arranged between the layers of the first and third semiconductors, and the bandgap energy of the second semiconductor may be smaller than those of the first and third semiconductors such that the layers of the first and third semiconductors form confinement potential barriers to electrons or holes intended to be located in the confinement regions formed in the layer of the second semiconductor.

In this second embodiment, the confinement regions may be located in the layer of the second semiconductor, vertically in line with the cavities or in the vicinity of these.

Advantageously, in this second embodiment, the first and third semiconductors may be SiGe and the second semiconductor may be Si (allowing confining electrons) or Ge (allowing confining holes), or the first and third semiconductors may be AlGaAs and the second semiconductor may be GaAs.

The thickness of the layer of the second semiconductor may be comprised between 5 nm and 50 nm and advantageously between 10 nm and 20 nm, and/or the thickness of the layer of the first semiconductor may be comprised between 5 nm and 200 nm and advantageously between 10 nm and 100 nm, and/or the thickness of a portion of the layer of the first semiconductor arranged under the cavities may be smaller than the thickness of the layer of the first semiconductor and comprised between 5 nm and 100 nm and advantageously between 5 and 30 nm.

The quantum device may further include at least one layer of a dielectric material arranged at least between walls of each of the cavities and each of the control gates.

The layer of a dielectric material may have a thickness smaller than or equal to 20 nm and advantageously smaller than or equal to 10 nm.

The qubits may be arranged so as to form a qubit matrix.

A method for making a quantum device with semiconductor qubits is also provided, including at least:
making a layer of a first semiconductor over a layer of a second semiconductor which bandgap energy is different from that of the first semiconductor, such that one of the layers forms a confinement potential barrier to electrons or holes to be located in confinement regions formed in the other layer;
making cavities through a portion of the thickness of the layer of the first semiconductor;
making electrically-conductive control gates, each arranged at least partially in one of the cavities.

Advantageously, the cavities may be made by local etching of the first semiconductor, and the gates may be made by filling these cavities with metal, thereby allowing obtaining gates that are self-aligned with respect to the confinement regions.

Throughout the document, the term “on” is used without distinction of the orientation in the space of the element to which this term refers. For example, in the feature “on a face of a layer”, this face is not necessarily oriented upwards but may correspond to a face oriented according to any direction. Furthermore, the arrangement of a first element on a second element should be understood as being able to correspond to the arrangement of the first element directly against the second element, without any intermediate element between the first and second elements, or as being able to correspond to the arrangement of the first element on the second element with one or more intermediate element(s) arranged between the first and second elements.

### BRIEF DESCRIPTION OF THE DRAWINGS

The present invention will be better understood upon reading the description of embodiments given merely for indicative and in no way limiting purposes with reference to the appended drawings, wherein:

FIGS. 1, 2 and 3 show steps of a method for making a quantum device with semiconductor qubits, object of the present invention, according to a first embodiment;

FIGS. 4 and 5 show a portion of the steps of a method for making a quantum device with semiconductor qubits, object of the present invention, according to a variant of the first embodiment;

FIGS. 6, 7 and 8 show steps of a method for making a quantum device with semiconductor qubits, object of the present invention, according to a second embodiment;

FIGS. 9 and 10 show a portion of the steps of a method for making a quantum device with semiconductor qubits, object of the present invention, according to a variant of the second embodiment;

FIG. 11 schematically shows a top view of an example of arrangement of several gates of a quantum device with semiconductor qubits, object of the present invention;

FIG. 12 shows results of simulations carried out to compare the susceptibility to charges disorder of a quantum device with semiconductor qubits, object of the present invention, with that of a quantum device of the prior art.

Identical, similar or equivalent portions of the different figures described hereinafter bear the same reference numerals so as to facilitate passage from one figure to another.

The different portions shown in the figures are not necessarily plotted according to a uniform scale, in order to make the figures more legible.

The different possibilities (variants and embodiments) should be understood as not being exclusive of one another and could be combined together.

### DETAILED DESCRIPTION OF PARTICULAR EMBODIMENTS

In the description hereinbelow, for simplification, only making of the control gates of a quantum device with semiconductor qubits is described. The other elements or features of this device, in particular with regards to the coupling between qubits and the other control and measurement elements, are not described.

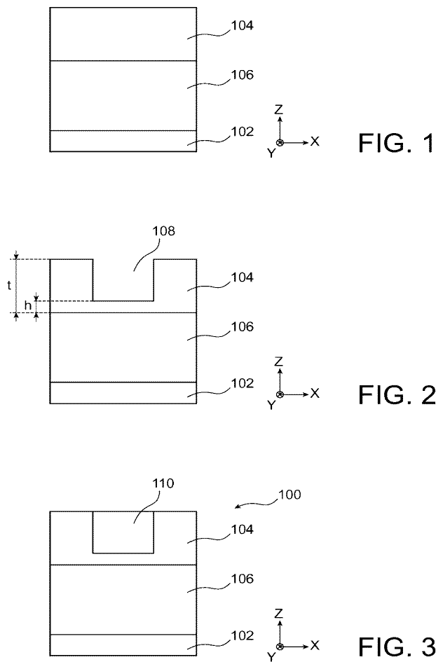

An example of a method for making a quantum device 100 with semiconductor qubits according to a first embodiment is described hereinbelow with reference to FIGS. 1 to 3 which correspond to sectional views of the device made. In the example described in these figures, making of the gate of one single qubit is described. Nonetheless, this method is implemented to make a quantum device 100 including several qubits for example arranged in the form of a matrix and such that each qubit could interact with one or more neighbouring qubit(s).

This method is implemented starting from a substrate 102 corresponding for example to a wafer based on Si, Ge, GaAs, or another semiconductor.

Epitaxy steps are implemented in order to form, over the substrate 102, a stack of semiconductors comprising at least one layer 104 of a first semiconductor and one layer 106 of a second semiconductor forming together a heterostructure (cf. FIG. 1). The layer 106 is arranged between the substrate 102 and the layer 104. For example, the thickness t (dimension parallel to the axis Z shown in FIG. 1, and parallel to the direction of the stack or direction of growth of the layers 104, 106) of the layer 104 is comprised between 5 nm and 200 nm and advantageously between 10 nm and 100 nm. For example, the thickness of the layer 106 is comprised between a few nanometres and 10 micrometres or more. A large thickness may be necessary in some cases to relieve stresses induced by lattice differences between the layer 106 and the substrate 102. The stoichiometric composition of layer 106 may vary during epitaxial growth in order to obtain the desired composition at the top of layer 106 with the desired stress state. The portion of the layer 106 comprising the desired composition, or the entire layer 106 when this layer includes the desired composition across its entire thickness, may have a thickness for example comprised between 5 nm and 50 nm and advantageously between 10 nm and 20 nm.

The first and second semiconductors of the layers 104, 106 are selected such that the bandgap energy of the second semiconductor is different from that of the first semiconductor, so that, in each of the qubits made, one of the layers 104, 106 forms a confinement potential barrier to electrons or holes intended to be located in confinement regions formed in the other one of the layers 104, 106.

In a first configuration, the bandgap energy of the second semiconductor of the layer 106 is lower than that of the first semiconductor of the layer 104, so that, in each of the qubits made, the potential barrier is formed by the first semiconductor of the layer 104 and the confinement region is formed in the second semiconductor of the layer 106 proximate to the interface with the first semiconductor. According to an example of this first configuration wherein the qubits of the device 100 are spin (or charge) qubits of electrons (or holes), the first semiconductor of the layer 104 is AlGaAs and the second semiconductor of the layer 106, as well as of the substrate 102, are GaAs. According to another example of this first configuration wherein the qubits of the device 100 are electron spin or charge qubits, the first semiconductor of the layer 104 is SiGe and the second semiconductor of the layer 106 is Si. According to another example of this first configuration wherein the qubits of the device 100 are hole spin or charge qubits, the first semiconductor of the layer 104 is SiGe and the second semiconductor of the layer 106 is Ge.

In a second configuration, the bandgap energy of the first semiconductor of the layer 104 is lower than that of the second semiconductor of the layer 106, so that, in each of the qubits made, the potential barrier is formed by the second semiconductor of the layer 106 and the confinement region is formed in the first semiconductor of the layer 104 proximate to the interface with the second semiconductor. The examples of materials described hereinabove for the first configuration could be applied to this second configuration, by interchanging the materials of the layers 104, 106.

After making the layers 104, 106 over the substrate 102, cavities 108 are made through only one portion of the thickness t of the layer 104 (in FIG. 2, one single cavity 108 is shown). For example, the cavities 108 are obtained through a controlled process of partial etching of the layer 104. Each of the cavities 108 has, in a plane parallel to the upper face of the layer 104 through which the cavities 108 are made (and parallel to the plane (X, Y) shown in FIG. 2), a section for example in the form of a disk or polygon including the case of a very anisotropic shape, for example narrow in one direction and long in another direction.

The thickness h of the remaining portion of the layer 104 located under the cavities 108 is smaller than the initial thickness t of the layer 104 and is for example comprised between 5 nm and 100 nm and advantageously between 5 and 30 nm.

Afterwards, electrically-conductive control gates 110 are made in the cavities 108 (cf. FIG. 3 on which one single gate 110 is shown). In the described embodiment, the gates 110 include at least one metallic material. The gates 110 may be made by depositing one or more metallic material(s) in each of the cavities 108, thereby allowing having a self-aligned implementation of these gates 110. Portions of this or these metallic material(s) deposited outside the cavities 108 could be removed by chemical mechanical planarisation (CMP) or another method. In this case, the gate material 110 may be flush with the same level as an upper face of the layer 104. Advantageously, it is possible to perform filling so as to completely fill each cavity 108 with a gate 110.

The device 100 obtained at this stage includes several qubits controlled by gates 110. The number of gates is typically equal to or greater than the number of qubits.

Some of the gates 110 may be used to modulate the tunnel couplings between the qubits. In general, a higher number of gates enables a better control of the confinement potentials of the qubits, thereby facilitating handling and coupling thereof.

The gates 110, or a portion of these gates 110, may be arranged vertically in line with electrons (or holes) confinement regions formed in the layer 106 (case of the first configuration described before) or in the layer 104 (case of the second configuration described before). This corresponds to the case where these gates 110 act in accumulation mode by attracting the electrons (or the holes) below themselves.

Alternatively, in the case where a two-dimensional electron gas (or holes) is already present in the absence of potentials applied to the gates 110, the gates 110 or a portion of these gates 110 can act in depletion mode by pushing the electrons (or the holes). As a result, the electrons (or holes) qubits are located between the gates 110, either in the layer 106 (case of the first configuration described before), or in the layer 104 (case of the second configuration described before). This electron or holes gas may result:
from an intentional doping, for example of the layer 104. The carriers released in the layer 104 are in this case captured by the layer 106 which bandgap is smaller. This intentional doping is generally introduced into an atomic plane of the layer 104 (“delta doping” type doping), with densities for example comprised between 10¹¹ and 10¹⁷ at/cm²,
from a doping due to the presence of defects at the interface between the layer 104 and the surface of the device which release charges,
from the presence of an overall gate at the rear face (under the layer 106, for example formed by the substrate 102 itself). When properly polarised, this overall gate attracts carriers in the layer 106, and the resulting gas is then depleted, or emptied of its charges, locally with the gates 110.

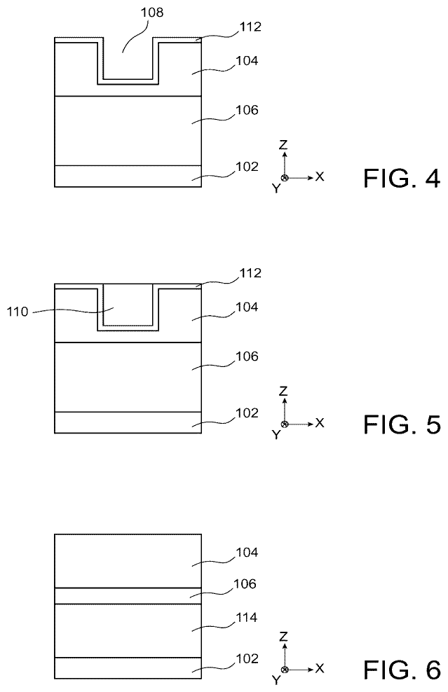

A variant of the first embodiment is described hereinbelow with reference to FIGS. 4 and 5. In the example described in these figures, making of the gat of one single qubit is described. Nonetheless, like before, this method is implemented to make a quantum device 100 including several qubits for example arranged in the form of a matrix and such that each qubit could interact with one or more neighbouring qubit(s).

Like in the previously-described example, the stack of layers 104 and 106 is made over the substrate 102. Afterwards, the cavities 108 are made through a portion of the thickness t of the layer 104.

As shown in FIG. 4, a layer 112 of a dielectric material is deposited afterwards against the walls (bottom wall and lateral walls) of the cavities 108 (one single cavity 108 is shown in FIG. 4). The implemented deposition corresponds to a conformal deposition, i.e. the thickness of the layer 112 is substantially constant over all of the walls covered by the layer 112. The layer 112 could then entirely cover the bottom wall as well as the lateral walls of the cavity 108. Advantageously, the thickness of the layer 112 is smaller than or equal to 10 nm. For example, the dielectric material of the layer 112 corresponds to an oxide such as Al₂O₃ or SiO₂, or to a nitride such as AlN or Si₃N₄, or to another dielectric material. Alternatively, the layer 112 could correspond to a stack of several different dielectric materials.

Afterwards, the gates 110 are made in the cavities 108, on the layer 112 such that the layer 112 is arranged between the walls of the cavities 108 and the gates 110 (one single gate 110 is visible in FIG. 5). Like before, each of the gates 110 includes at least one metallic material. The gates 110 may be made by depositing one or more metallic material(s) in each of the cavities 108. Portions of this or these metallic material(s) deposited outside the cavities 108 can be removed by CMP or by other methods.

In the example shown in FIGS. 4 and 5, portions of the layer 112 are arranged outside the cavities 108. These portions of the layer 112 could be removed before or after the gates 110 have been made. Advantageously, in this embodiment, each cavity 108 may be entirely filled with a stack formed of the layer 112 of a dielectric material and by the gate.

An example of a method for making a quantum device 100 with semiconductor qubits according to a second embodiment is described hereinbelow with reference to FIGS. 6 to 8 corresponding to sectional views of the device being made. In the example described in these figures, making of the gate of one single qubit is described. Nonetheless, this method is implemented to make a quantum device 100 including several qubits for example arranged in the form of a matrix and such that each qubit could interact with one or more neighbouring qubit(s).

Like in the first embodiment, epitaxy steps are implemented in order to form, over the substrate 102, a stack of semiconductors forming a heterostructure. Besides the layers 104 and 106 similar to those made in the first embodiment, the stack made over the substrate 102 also includes a layer 114 of a third semiconductor such that the layer 106 of the second semiconductor is arranged between the layers 104 and 114.

In this second embodiment, the first, second and third semiconductors of the layers 104, 106 and 114 are selected such that the bandgap energy of the second semiconductor is lower than those of the first and third semiconductors. Thus, the layers 104 and 114 of the first and third semiconductors form confinement potential barriers to electrons or holes intended to be located in confinement regions formed in the layer 106 of the second semiconductor.

In this stack, the first and third semiconductors of the layers 104 and 114 are therefore intended to form potential barriers with respect to confinement regions formed in the second semiconductor of the layer 106. When the first and third semiconductors are SiGe and the second semiconductor is Si, the charge carriers intended to be confined are electrons, whereas when the first and third semiconductors are SiGe and the second semiconductor is Ge, the charge carriers intended to be confined are holes.

For example, the thickness t of the layer 104 is similar to that one described before in the first embodiment. For example, the thickness of the layer 106 is comprised between 5 nm and 50 nm and advantageously between 10 nm and 20 nm.

The thickness of the layer 114 may vary between a few nanometres and typically 10 micrometres or more. This thickness is selected according to the possible need for relieving the stresses induced by differences in the lattice parameter between the layer 114 and the substrate 102. The stoichiometric composition of the layer 114 may vary during the epitaxial growth in order to end with the desired composition with the desired stress state.

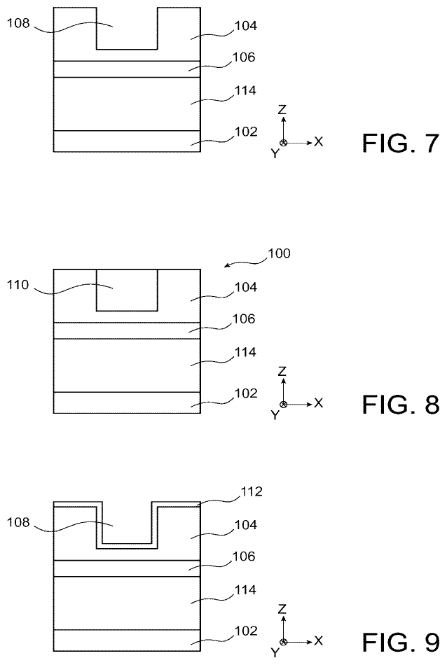

Like in the first embodiment described before, the cavities 108 are made afterwards in a portion of the thickness t of the layer 104 (cf. FIG. 7 on which one single cavity 108 is visible), then the gates 110 are made in the cavities 108 (cf. FIG. 8 on which one single gate 110 is visible).

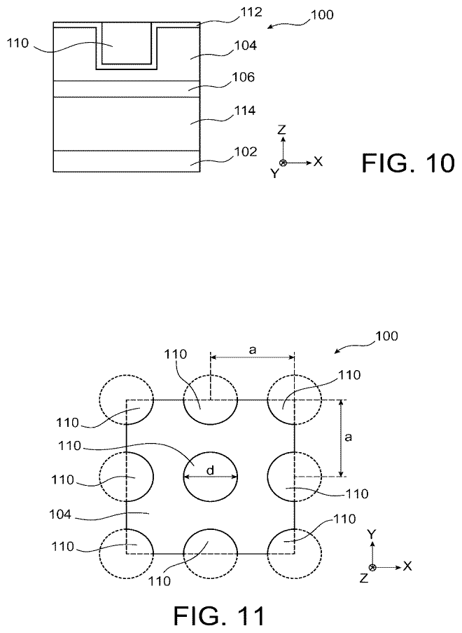

A variant of the second embodiment is described hereinbelow with reference to FIGS. 9 and 10. In the example described in these figures, making of the gate of one single qubit is described. Nonetheless, like before, this method is implemented to make a quantum device 100 including several qubits for example arranged in the form of a matrix and such that each qubit could interact with one or more neighbouring qubit(s).

Like in the previously-described example, the stack of layers 104, 106 and 114 is made over the substrate 102. Afterwards, the cavities 108 are made through a portion of the thickness t of the layer 104.

As shown in FIG. 9, a layer 112 of a dielectric material, for example similar to that one described before with reference to FIGS. 4 and 5, is deposited afterwards against the walls (bottom wall and lateral walls) of the cavities 108 (one single cavity 108 is visible in FIG. 9). The implemented deposition corresponds to a conformal deposition.

Afterwards, the gates 110 are made in the cavities 108, over the layer 112 such that the layer 112 is arranged between the walls of the cavities 108 and the gates 110 (one single gate 110 is visible in FIG. 10). Like before, the gates 110 include at least one metallic material. The gates 110 may be made by depositing one or more metallic material(s) in each of the cavities 108. Portions of this or these metallic material(s) deposited outside the cavities 108 could be removed by CMP or lift-off or a process of controlled etching possibly through a masking layer having undergone a lithography step beforehand.

The different variants and alternatives described before for the first embodiment could apply to the second embodiment.

FIG. 11 schematically shows a top view of an example of arrangement of several gates 110 of a device 100 including several qubits. In this example, each gate 110 includes a section, in the upper face plane of the layer 104 through which the gates 110 are made, in the form of a disk, and with a diameter d for example comprised between 10 nm and 200 nm. Furthermore, the centres of two neighbouring gates 110 are spaced apart by a distance a for example comprised between 10 nm and 250 nm and larger than the diameter d. Of course, other shapes of gates may be considered.

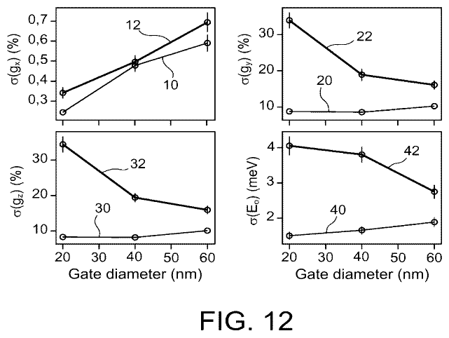

FIG. 12 shows results of simulations carried out in order to compare the susceptibility to disorder of charges of a device 100 including several qubits which gates are made as shown in FIG. 11 with regards to a quantum device of the prior art including several qubits, which elements are made with the same materials (first and third semiconductors corresponding to Si_{0.2}Ge_{0.8}; second semiconductor corresponding to Ge) and the same dimensions as for the device 100, but which gates are made over the upper surface of a semiconductor layer (and not in a cavity formed beforehand in the semiconductor layer like in device 100). In order to obtain an appropriate comparison, the thickness of the semiconductor layer over which the gates are made in the prior art device is selected as being equal to the thickness of the remaining portions of the layer 104 located under the cavities of the simulated device 100 in order to ensure essentially the same level of electrostatic coupling between the control gates and the electrons or holes in the underlying quantum dots.

In FIG. 12, the curves 10, 20 and 30 represent, for the device 100, the variability, or standard deviation, of the gyromagnetic factors according to each of the axes X, Y and Z for values of the gate diameter d ranging from 20 nm to 60 nm. The curves 12, 22 and 32 represent these same values for the quantum device of the prior art including the gates made above the semiconductor layer. The curve 40 represents the variability of the energy level E₀ of the first hole confined in one of the quantum dots of the device 100 for values of the gate diameter d ranging from 20 nm to 60 nm, and the curve 42 represents the variability of this same energy level E₀ for the quantum device of the prior art including the gates made above the semiconductor layer. The results shown in FIG. 12 have been obtained with the following parameters:
average density of charge at the interface between the first semiconductor and the dielectric layer equal to 10¹¹ cm⁻²;
thickness h=20 nm;
thickness t of the layer 104=100 nm;
distance a=80 nm.

These simulations implicitly imply that the interfacial charges which are located between the gates generate an electrostatic disorder much greater than the charges located on the interfaces covered by the metallic gates. This is a consequence of the screening effect by the gate itself. Hence, the use of gates 110 as proposed in the device 100 allows moving the less screened charges away (trapped at the surface between the gates), thereby reducing the variability due to charge disorder. The higher the ratios a/d and t/h (with t corresponding to the thickness of the layer 104 in which the gates 110 are made), the more the use of gates as proposed in the device 100 is advantageous. In particular, these simulations showing that the variability of the energy level E₀ could be reduced by a factor of 4 if a/d>2. The variability decreases with the ratio t/h down to t/h=3 and it has the tendency to saturate for t/h>3. In the simulations which results are shown in FIG. 12, the value of the ratio t/h is equal to 5.

1. A quantum device with semiconductor qubits, the quantum device comprising:
a layer of a first semiconductor arranged over a layer of a second semiconductor having a bandgap energy is different from that of the first semiconductor, such that one of the layers forms a confinement potential barrier to electrons or holes intended to be located in confinement regions formed in the other layer;
cavities formed through only a portion of a thickness of the layer of the first semiconductor, and
electrically-conductive control gates, each arranged at least partially in one of the cavities.

2. The quantum device according to claim 1, wherein each of the control gates includes at least a metallic material.

3. The quantum device according to claim 1, wherein:
the semiconductor of said one of the layers forming the confinement potential barrier is AlGaAs and the semiconductor of said other layer is GaAs, or
the semiconductor of said one of the layers forming the confinement potential barrier is SiGe and the semiconductor of said other layer is Si or Ge.

4. The quantum device according to claim 1, further including a layer of a third semiconductor such that the layer of the second semiconductor is arranged between the layers of the first and third semiconductors, and wherein the bandgap energy of the second semiconductor is smaller than those of the first and third semiconductors such that the layers of the first and third semiconductors form confinement potential barriers to electrons or holes intended to be located in the confinement regions formed in the layer of the second semiconductor.

5. The quantum device according to claim 4, wherein:
the first and third semiconductors are SiGe and the second semiconductor is Si or Ge, or
the first and third semiconductors are AlGaAs and the second semiconductor is GaAs.

6. The quantum device according to claim 1, wherein a thickness of the layer of the second semiconductor is between 5 nm and 50 nm, and/or wherein the thickness of the layer of the first semiconductor is between 5 nm and 200 nm, and/or wherein a thickness of a portion of the layer of the first semiconductor arranged under the cavities is smaller than the thickness of the layer of the first semiconductor and comprised between 5 nm and 100 nm.

7. The quantum device according to claim 1, further including at least one layer of a dielectric material arranged at least between walls of each of the cavities and each of the control gates.

8. The quantum device according to claim 7, wherein the layer of the dielectric material has a thickness smaller than or equal to 20 nm.

9. The quantum device according to claim 1, wherein the qubits are arranged so as to form a qubit matrix.

10. A method for making a quantum device with semiconductor qubits, the method comprising:
making a layer of a first semiconductor over a layer of a second semiconductor having a bandgap energy different from that of the first semiconductor, such that one of the layers forms a confinement potential barrier to electrons or holes to be located in confinement regions formed in the other layer;
making cavities through a portion of the thickness of the layer of the first semiconductor; and
making electrically-conductive control gates, each arranged at least partially in one of the cavities.

11. The quantum device according to claim 6, wherein the thickness of the layer of the second semiconductor is between 10 nm and 20 nm, and/or the thickness of the layer of the first semiconductor is between 10 nm and 100 nm, and/or the thickness of a portion of the layer of the first semiconductor arranged under the cavities is smaller than the thickness of the layer of the first semiconductor and between 5 and 30 nm.

12. The quantum device according to claim 8, wherein the layer of a dielectric material has a thickness smaller than or equal to 10 nm.
